(19) United States
(12) Patent Application Publication
(10) Pub. No.: US 2014/0102500 A1
(43) Pub. Date: Apr. 17, 2014

(54) Thermoelectric Device Assembly, Thermoelectric Module and its Manufacturing Method

(71) Applicant: Hitachi Chemical Company, Ltd., Tokyo (JP)

(72) Inventors: Shinichi FUJIWARA, Tokyo (JP); Tomotake TOHEI, Tokyo (JP); Zenzo ISHIJIMA, Tokyo (JP); Takahiro JINUSHI, Tokyo (JP); Shohei HATA, Tokyo (JP)

(73) Assignee: Hitachi Chemical Company, Ltd., Tokyo (JP)

(21) Appl. No.: 14/050,883

(22) Filed: Oct. 10, 2013

(30) Foreign Application Priority Data
Oct. 12, 2012 (JP) 2012-226858

(51) Int. Cl. H01L 35/32; H01L 35/34

(52) U.S. Cl. CPC H01L 35/32; H01L 35/34
USPC 136/205; 438/54; 136/201

(57) ABSTRACT

In a structure for joining thermoelectric devices and electrodes in a thermoelectric module, the thermoelectric module is configured such that multiple P-type thermoelectric devices and multiple N-type thermoelectric devices are alternately disposed so as to be electrically connected in series via electrode members. A connected portion of the electrode member to the P-type thermoelectric device and a connected portion of the electrode member to the N-type thermoelectric device are made of different materials. This can suppress a considerable reduction in connection reliability between the thermoelectric devices and the electrodes even at a high temperature and efficiently transmit a peripheral temperature to the thermoelectric devices.

### CLAIM OF PRIORITY

The present application claims priority from Japanese Patent Application JP 2012-226858 filed on Oct. 12, 2012, the content of which is hereby incorporated by reference into this application.

### BACKGROUND

The present invention relates to a thermoelectric device assembly with higher connection reliability between a thermoelectric device and an electrode, a thermoelectric module, and its manufacturing method.

A thermoelectric module that converts thermal energy to electric energy by the Seeback effect features the absence of a drive unit and the provision of a definite structure with no maintenance requirement. Such thermoelectric modules have been used only for products such as satellite power supplies because of its low conversion efficiency; meanwhile, such thermoelectric modules have received attention as a technique of collecting waste heat as thermal energy to realize an environmentally friendly society. The application of the technique to incinerators, industrial furnaces, and vehicle related products has been examined. Against this backdrop, thermoelectric modules with higher durability and higher conversion efficiency have been demanded at lower cost.

In a thermoelectric module, heat can be converted to electricity according to a temperature difference in a thermoelectric device. Thus, a stress is generated at a joint between the thermoelectric device and an electrode by a difference in coefficient of thermal expansion between the thermoelectric device and the electrode in an operating environment. This may cause a break at the joint or in the thermoelectric device. The stress generated thus increases with an ambient temperature or a difference in coefficient of thermal expansion between the thermoelectric device and a bonding material or the electrode.

### SUMMARY

It is known that thermoelectric devices have different temperature ranges with high conversion efficiency depending upon device materials. Moreover, a thermoelectric device may contain only one of a P-type material and an N-type material. Thus, in many cases, a combination of different device materials of P-type and N-type may constitute a thermoelectric module. Since coefficients of thermal expansion vary with device materials, a stress may concentrate at a connection between a device and an electrode because of a heat load during bonding and a temperature change during an operation. A stress at the connection may crack the device and the joint, considerably reducing the connection reliability.

The present invention provides a thermoelectric device assembly, a thermoelectric module, and its manufacturing method which can obtain high reliability and efficiently transmit a peripheral temperature to a thermoelectric device even at a high temperature or in an environment where a thermal stress is generated by a thermal cycle.

In order to solve the problem, the present invention is a thermoelectric device assembly including a P-type thermoelectric device and an N-type thermoelectric device that are electrically connected in series via an electrode member, wherein the electrode member has a portion connected to the P-type thermoelectric device according to the coefficient of thermal expansion of the P-type thermoelectric device and a portion connected to the N-type thermoelectric device according to the coefficient of thermal expansion of the N-type thermoelectric device, and the connected portion of the electrode to the P-type thermoelectric device and the connected portion of the electrode to the N-type thermoelectric device are made of different materials.

The present invention is a thermoelectric module including multiple P-type thermoelectric devices and multiple N-type thermoelectric devices that are alternately disposed so as to be electrically connected in series, wherein each of the electrode members has a portion connected to each of the P-type thermoelectric devices according to the coefficient of thermal expansion of the P-type thermoelectric devices and a portion connected to each of the N-type thermoelectric devices according to the coefficient of thermal expansion of the N-type thermoelectric devices, and the connected portion of each of the electrode members to each of the P-type thermoelectric devices and the connected portion of each of the electrode members to each of the N-type thermoelectric device are made of different materials.

In order to solve the problem, a method of manufacturing a thermoelectric module according to the present invention includes the steps of: disposing multiple electrode members, each being made of at least two materials with a first area composed of a first material joined to one of P-type thermoelectric devices according to the coefficient of thermal expansion of the P-type thermoelectric devices and a second material joined to one of N-type thermoelectric devices according to the coefficient of thermal expansion of the N-type thermoelectric devices; alternately disposing the P-type thermoelectric devices and the N-type thermoelectric devices with high temperature surfaces flush with each other and low temperature surfaces flush with each other; and electrically connecting each of the P-type thermoelectric devices and each of the N-type thermoelectric devices in series by joining each of the alternately disposed P-type thermoelectric devices to each of the electrode members in the first area of each of the electrode members and joining each of the N-type thermoelectric devices to each of the electrode members in the second area of each of the electrode members.

According to embodiments of the present invention, for the P-type thermoelectric device and the N-type thermoelectric device having different coefficients of thermal expansion, electrodes are made of materials having coefficients of thermal expansion close to those of the thermoelectric devices. This can suppress a thermal stress generated between the thermoelectric device and the electrode, achieving high connection reliability even in an actual use environment. The thermoelectric devices can be joined in a process similar to a conventional process without the need for additional bonding process.

These features and advantages of the invention will be apparent from the following more particular description of preferred embodiments of the invention, as illustrated in the accompanying drawings.

### BRIEF DESCRIPTION OF THE DRAWINGS

Embodiments of the present invention will be described in detail based on the following figures, wherein:

FIG. 1 is a side view of the vicinity of devices in a thermoelectric module for reducing a joint stress according to a first embodiment of the present invention;

FIGS. 2A to 2C are flow side views showing the steps of a method of manufacturing the thermoelectric module for reducing a joint stress according to the first embodiment of the present invention;

FIG. 3 is a perspective view of a structural example of the thermoelectric module for reducing a joint stress according to the first embodiment of the present invention;

FIG. 4 is a side view of the vicinity of devices in a thermoelectric module for reducing a joint stress according to a second embodiment of the present invention;

FIG. 5 is a side view of the vicinity of devices in a thermoelectric module for reducing a joint stress according to a third embodiment of the present invention; and

FIG. 6 is a side view of the vicinity of devices in a conventional thermoelectric module.

### DESCRIPTION OF THE PREFERRED EMBODIMENTS

According to embodiments of the present invention, for a P-type thermoelectric device and an N-type thermoelectric device with different coefficients of thermal expansion in a thermoelectric module, electrodes are made of materials having coefficients of thermal expansion close to those of the device materials of the thermoelectric devices, and the devices are connected to the respective electrode members via bonding materials.

Embodiments of the present invention will be described below with reference to the accompanying drawings.

### First Embodiment

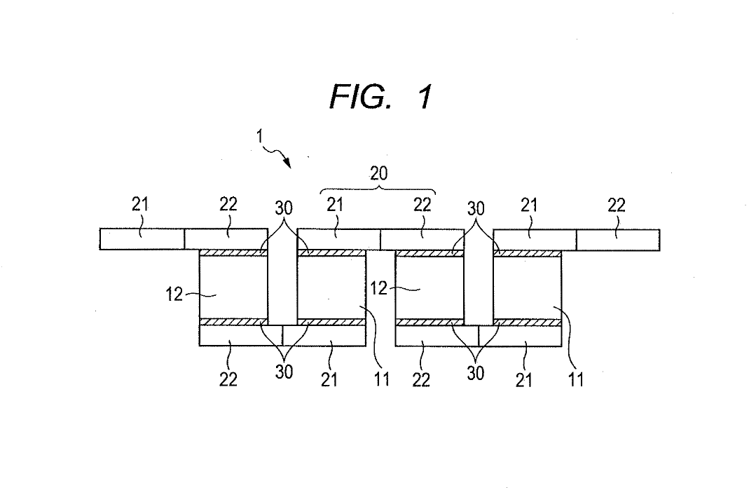

FIG. 1 is a side view of the vicinity of devices in a thermoelectric module for reducing a joint stress according to a first embodiment of the present invention. Reference numeral 1 denotes a thermoelectric device assembly, reference numeral 11 denotes a P-type thermoelectric device, reference numeral 12 denotes an N-type thermoelectric device, reference numeral 20 denotes an electrode assembly, reference numeral 21 denotes a P-type electrode, reference numeral 22 denotes an N-type electrode, and reference numeral 30 denotes a bonding material. The P-type thermoelectric device 11 and the N-type thermoelectric device 12 are made of materials having thermoelectric conversion characteristics, for example, silicon-germanium, iron-silicon, bismuth-tellurium, magnesium-silicon, lead-tellurium, cobalt-antimony, bismuth-antimony, a Heusler alloy, and a half Heusler alloy. The P-type electrode 21 and the N-type electrode 22 are desirably made of nickel, molybdenum, titanium, iron, copper, manganese, tungsten, or an alloy mainly composed of one of the metals. The bonding material 30 is desirably aluminum, nickel, tin, copper, zinc, germanium, magnesium, gold, silver, indium, lead, bismuth, tellurium, or an alloy mainly composed of one of the metals.

In the following embodiment, the P-type thermoelectric device 11 is made of silicon and germanium powder containing impurities of 1% or less with P-type semiconductor properties, for example, boron, aluminum, and gallium while the N-type thermoelectric device 12 is made of silicon and germanium powder containing impurities of 10% or less with N-type semiconductor properties, for example, aluminum. The thermoelectric devices are formed by sintering the powder by pulse discharge, hot pressing, and other methods. Specifically, in the present embodiment, the P-type thermoelectric device 11 is a silicon-germanium device while the N-type thermoelectric device 12 is a silicon-magnesium device. Furthermore, the P-type electrode 21 is made of molybdenum (a coefficient of thermal expansion of 5.8×10⁻⁶K⁻¹) while the N-type electrode 22 is made of nickel (a coefficient of thermal expansion of 15.2×10⁻⁶K⁻¹).

The P-type electrode 21 and the N-type electrode 22 may be joined to each other by any methods as long as remelting does not occur under a use environment. For example, the electrodes may be joined with a base material directly melted by electron beam welding, arc welding, spot welding, TIG welding, and other methods. Alternatively, the electrodes may be joined by solid-phase bonding such as a rolling process with a clad metal or may be joined with a bonding material such as a brazing filler metal.

As shown in FIG. 1, the upper end of the P-type thermoelectric device 11 and the lower end of the P-type electrode 21 are joined to each other with the bonding material 30 while the upper end of the N-type thermoelectric device 12 and the lower end of the N-type electrode 22 are joined to each other with the bonding material 30. In the thermoelectric module, an electromotive force is generated according to a temperature difference between both ends of the thermoelectric device. In FIG. 1, the top surface of the thermoelectric device has a high temperature while the undersurface of the thermoelectric device has a low temperature.

A temperature difference between the top surface and the undersurface of the thermoelectric device assembly makes an electric current pass through the thermoelectric device assembly 1. The electric current flows from the high temperature side to the low temperature side in the P-type thermoelectric device 11 (from the top to the bottom in FIG. 1) while the current flows from the low temperature side to the high temperature side in the N-type thermoelectric device 12 (from the bottom to the top in FIG. 1). Thus, the thermoelectric devices connected in series form an electric circuit. The thermoelectric devices connected in series are joined on a flat surface or a line, constituting the thermoelectric device assembly 1.

In this configuration, the P-type thermoelectric device 11 that is a silicon-germanium device has a coefficient of thermal expansion of 4.5×10⁻⁶K⁻¹ while the N-type thermoelectric device 12 that is a silicon-magnesium device has a coefficient of thermal expansion of 15.5×10⁻⁶K⁻¹. It is found that an amount of expansion/contraction varies between the P-type thermoelectric device 11 and the N-type thermoelectric device 12 during heating in a joining process or a temperature change in an actual use environment. In the case where the thermoelectric device is joined to the electrode, a stress and distortion are generated near the joint by a difference in coefficient of thermal expansion between an electrode member and the thermoelectric device. Thus, the joint may be broken or peeled, or a crack may occur on the P-type thermoelectric device 11 or the N-type thermoelectric device 12.

In the structure of the present embodiment, however, a difference in coefficient of thermal expansion is 1.3×10⁻⁶K⁻¹ between the P-type thermoelectric device 11 composed of silicon-germanium (a coefficient of thermal expansion of 4.5×10⁻⁶K⁻¹) and the P-type electrode 21 composed of molybdenum (a coefficient of thermal expansion of 5.8×10⁻⁶K⁻¹). Such a small difference in coefficient of thermal expansion can reduce a stress or distortion near the joints of the P-type thermoelectric device 11. Similarly, a difference in coefficient of thermal expansion is 0.3×10⁻⁶K⁻¹ between the N-type thermoelectric device 12 composed of silicon-magnesium (a coefficient of thermal expansion of 15.5×10⁻⁶K⁻¹) and the N-type electrode 22 composed of nickel (a coefficient of thermal expansion of 15.2×10⁻⁶K⁻¹). This can reduce a stress and distortion near the joints of the N-type thermoelectric device 12, forming the joints with high connection reliability.

Furthermore, in the present embodiment, a stress buffer layer does not need to be formed beforehand on the thermoelectric device. This can simplify the manufacturing process of the thermoelectric devices while reducing the total number of configurations in the thickness direction, leading to smaller variations in height.

Moreover, the joining pattern of the present embodiment reduces the absolute values of a stress and distortion on the joint as compared with a configuration disclosed in Japanese Patent Laid-Open No. 9-293906 in which, as described in FIG. 6, a P-type thermoelectric device 611 and an N-type thermoelectric device 612 are joined with a bonding material 631 to an electrode 625 made of a single material. Hence, by the present embodiment, even at a use environment temperature close to 600° C., a considerable reduction in connection reliability can be suppressed.

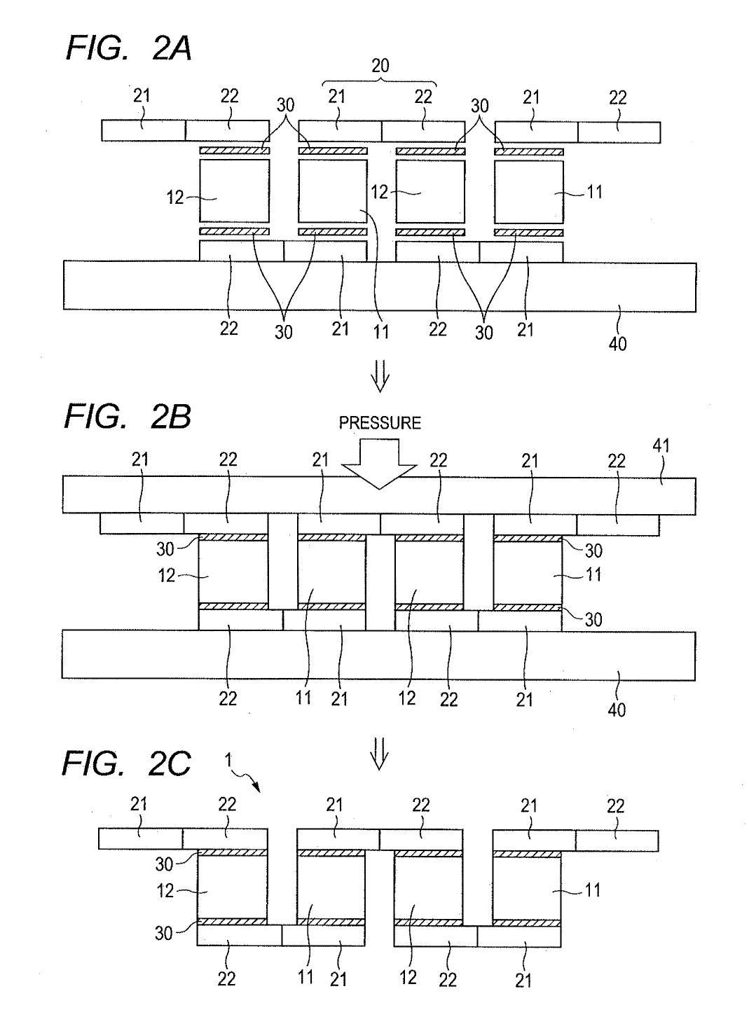

FIGS. 2A to 2C are side views of the vicinity of the devices in an assembling process example of a thermoelectric module for reducing a joint stress according to the first embodiment of the present invention. Reference numeral 1 denotes the thermoelectric device assembly, reference numeral 11 denotes the P-type thermoelectric device, reference numeral 12 denotes the N-type thermoelectric device, reference numeral 20 denotes the electrode assembly, reference numeral 21 denotes the P-type electrode, reference numeral 22 denotes the N-type electrode, and reference numeral 30 denotes the bonding material. Reference numeral 40 denotes a support jig, and reference numeral 41 denotes a pressurization jig. The P-type thermoelectric device 11 and the N-type thermoelectric device 12 are made of materials having thermoelectric conversion characteristics, for example, silicon-germanium, iron-silicon, bismuth-tellurium, magnesium-silicon, lead-tellurium, cobalt-antimony, bismuth-antimony, a Heusler alloy, and a half Heusler alloy. The P-type electrode 21 and the N-type electrode 22 are desirably made of nickel, molybdenum, titanium, iron, copper, manganese, tungsten, or an alloy mainly composed of one of the metals.

The bonding material 30 is desirably aluminum, nickel, tin, copper, zinc, germanium, magnesium, gold, silver, indium, lead, bismuth, tellurium, or an alloy mainly composed of one of the metals. In the assembling process, the bonding material 30 is aluminum or aluminum alloy foil containing materials such as silicon and germanium in aluminum, or the bonding material 30 is aluminum or foil of powder containing materials such as silicon and germanium in aluminum. The support jig 40 may be made of materials such as ceramics and metals that are not melted in a joining process. The support jig 40 is desirably made of a material not reacting with the bonding material 30, or a surface of the support jig 40 desirably has an unreactive layer that suppresses a reaction. The flow of assembling the thermoelectric device assembly 1 will be described below with reference to the method of assembling the thermoelectric module in FIGS. 2A to 2C.

First, as shown in FIG. 2A, the electrode assembly 20 including the P-type electrode 21 and the N-type electrode 22 that are joined to each other is mounted on the support jig 40. After that, the bonding material 30 and the P-type thermoelectric device 11 are sequentially positioned and mounted on the P-type electrode 21 while the bonding material 30 and the N-type thermoelectric device 12 are sequentially positioned and mounted on the N-type electrode 22. The bonding material 30 is mounted again on each of the thermoelectric device. The electrode assembly 20 is located such that the P-type electrode 21 is mounted on the P-type thermoelectric device 11 while the N-type electrode 22 is mounted on the N-type thermoelectric device 12. In this case, the bonding material 30 is metal foil and desirably has a thickness of 1 μm to 500 μm. The electrodes may be simultaneously or separately mounted with a tool (not shown) by any methods.

Subsequently, as shown in FIG. 2B, the electrode assembly 20 is pressed and heated from above by the pressurization jig 41 so as to melt the bonding material 30, joining the P-type electrode 21 to the P-type thermoelectric device 11 via the bonding material 30 while joining the N-type electrode 22 to the N-type thermoelectric device 12 via the bonding material 30 (metallic joints). At this point, the electrodes are desirably joined with a load of at least 0.12 kPa. After that, as shown in FIG. 2C, the formed thermoelectric device assembly 1 is removed from the pressurization jig 41 and the support jig 40.

FIGS. 2A to 2C illustrate the process of simultaneously joining the upper and lower bonding materials 30. One of the bonding materials may be joined before the other of the bonding materials. For example, in the step of FIG. 2A, only the bonding material 30 and the thermoelectric devices may be first mounted near the support jig 40, and then the support jig 40 under the thermoelectric devices is heated to melt the bonding material 30, joining the thermoelectric devices to the electrode assembly 20 near the support jig 40. After that, the top surfaces of the thermoelectric devices may be joined to the electrode assembly 20 with the bonding material 30 so as to form the thermoelectric device assembly 1.

In this case, a pressure of at least 0.12 kPa is applied to prevent inclination of the P-type thermoelectric device 11 and the N-type thermoelectric device 12 during joining, and discharge a maximum amount of the bonding material 30 melted from the interface between the P-type thermoelectric device 11 and the N-type thermoelectric device 12. The upper limit of the pressure is not particularly limited but is set lower than the crushing strength of the device so as to prevent a break on the device. Specifically, the upper limit may be set at about 1000 MPa or less. In the present embodiment, a pressure of several MPa is sufficiently effective.

A joining atmosphere may be a non-oxidizing atmosphere. Specifically, the atmosphere may be a vacuum atmosphere, a nitrogen atmosphere, a nitrogen-hydrogen mixing atmosphere, and so on.

In the present embodiment, an example of the bonding material 30 is metal foil. The bonding material 30 may be aluminum powder or aluminum alloy powder containing aluminum primarily composed of silicon and germanium. In this case, a single powder may be used, a layer composed of various powders may be stacked, or mixed powder thereof may be used. In the use of these powders, a molded body formed by compacting only powder may be located only at a point of joining the P-type thermoelectric device 11 and the N-type thermoelectric device 12, powder may be applied only at a point of joining the thermoelectric device beforehand, or paste powder of resin or the like may be applied to a point of joining the thermoelectric device. The application of powder beforehand can omit the step of attaching foil, further simplifying the manufacturing process.

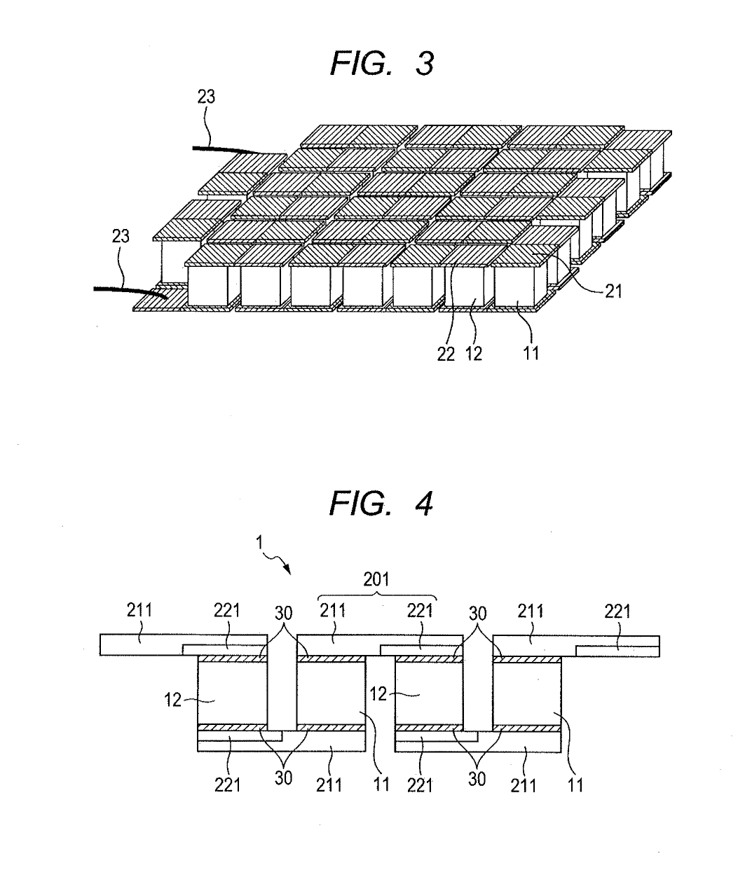

FIG. 3 is a perspective view illustrating a structural example of a joint stress reducing thermoelectric module according to the first embodiment of the present invention. In FIG. 3, 46 thermoelectric devices are joined in a lattice pattern. Reference numeral 11 denotes the P-type thermoelectric device, reference numeral 12 denotes the N-type thermoelectric device, reference numeral 21 denotes the P-type electrode, reference numeral 22 denotes the N-type electrode, and reference numeral 23 denotes extraction wirings. The extraction wirings are wires for collecting power generated in the thermoelectric devices. The extraction wirings may be made of any materials as long as the wires can be energized. A thermoelectric module in FIG. 3 is formed through the process of FIG. 2. The thermoelectric module may be stored in a case or may be used as it is.

As shown in FIG. 3, the P-type thermoelectric devices 11 and the N-type thermoelectric devices 12 are alternately connected via the P-type electrodes 21 and the N-type electrodes 22 so as to be electrically connected in series. The extraction wirings 23 are formed on both ends of the series connection to collect an electromotive force to the outside. In FIG. 3, the P-type thermoelectric device 11 and the N-type thermoelectric device 12 are square poles. The thermoelectric devices may be any poles such as square poles, triangle poles, polygonal columns, cylinders, and elliptic cylinders.

In the thermoelectric module according to the present embodiment, the P-type thermoelectric devices 11 and the N-type thermoelectric devices 12 may be connected via the electrode assemblies 20 so as to be electrically connected in series. The configuration illustrated in FIG. 3 may be two or more configurations electrically connected in parallel.

The present embodiment reduces a difference in coefficient of thermal expansion between the P-type thermoelectric device 11 and the P-type electrode 21 and a difference in coefficient of thermal expansion between the N-type thermoelectric device 12 and the N-type electrode 22. This suppresses a thermal stress generated between the thermoelectric device and the electrode at a high temperature and a thermal stress generated between the thermoelectric device and the electrode at a temperature fluctuating between a room temperature and a high temperature, achieving high reliability in an actual use environment. In this case, it is preferable to set a difference in coefficient of thermal expansion between the P-type thermoelectric device 11 and the P-type electrode 21 and a difference in coefficient of thermal expansion between the N-type thermoelectric device 12 and the N-type electrode 22 at an absolute value of 6×10⁻⁶K⁻¹ or less. An absolute value of 3×10⁻⁶K⁻¹ or less is more preferable, and an absolute value of 1.5×10⁻⁶K⁻¹ or less is still more preferable.

### Second Embodiment

Referring to FIG. 4, a second embodiment of the present invention will be described below.

As shown in FIG. 4, an electrode assembly 201 has a different shape from the electrode assembly 20 of the first embodiment.

FIG. 4 is a side view of the vicinity of devices in a joint stress reducing thermoelectric module according to the second embodiment of the present invention. Reference numeral 1 denotes a thermoelectric device assembly, reference numeral 11 denotes a P-type thermoelectric device, reference numeral 12 denotes an N-type thermoelectric device, reference numeral 201 denotes the electrode assembly, reference numeral 211 denotes a P-type electrode, reference numeral 221 denotes an N-type electrode, and reference numeral 30 denotes a bonding material.

The P-type thermoelectric device 11 and the N-type thermoelectric device 12 are made of materials having thermoelectric conversion characteristics, for example, silicon-germanium, iron-silicon, bismuth-tellurium, magnesium-silicon, lead-tellurium, cobalt-antimony, bismuth-antimony, a Heusler alloy, and a half Heusler alloy. The P-type electrode 221 and the N-type electrode 221 are desirably made of nickel, molybdenum, titanium, iron, copper, manganese, tungsten, or an alloy mainly composed of one of the metals. The bonding material 30 is desirably aluminum, nickel, tin, copper, zinc, germanium, magnesium, gold, silver, indium, lead, bismuth, tellurium, or an alloy mainly composed of one of the metals.

In the following embodiment, the P-type thermoelectric device 11 is made of silicon and germanium powder containing impurities of 1% or less with P-type semiconductor properties, for example, boron, aluminum, and gallium while the N-type thermoelectric device 12 is made of silicon and germanium powder containing impurities of 10% or less with N-type semiconductor properties, for example, aluminum. The thermoelectric devices are formed by sintering the powder by pulse discharge, hot pressing, and other methods. Specifically, in the present embodiment, the P-type thermoelectric device 11 is a silicon-germanium device while the N-type thermoelectric device 12 is a silicon-magnesium device. Furthermore, the P-type electrode 211 is made of molybdenum (a coefficient of thermal expansion of 5.8×10⁻⁶K⁻¹) while the N-type electrode 221 is made of nickel (a coefficient of thermal expansion of 15.2×10⁻⁶K¹).

The P-type electrode 211 and the N-type electrode 221 may be joined to each other by any methods as long as remelting does not occur under a use environment. For example, the electrodes may be joined with a base material directly melted by electron beam welding, arc welding, spot welding, TIG welding, and other methods. Alternatively, the electrodes may be joined by solid-phase bonding such as a rolling process with a clad metal or may be joined with a bonding material such as a brazing filler metal.

As shown in FIG. 4, the upper end of the P-type thermoelectric device 11 and the lower end of the P-type electrode 211 are joined to each other with the bonding material 30 while the upper end of the N-type thermoelectric device 12 and the lower end of the N-type electrode 221 are joined to each other with the bonding material 30. In the thermoelectric module, an electromotive force is generated according to a temperature difference between both ends of the thermoelectric device. In FIG. 1, the top surface of the thermoelectric device has a high temperature while the undersurface of the thermoelectric device has a low temperature.

A temperature difference between the top surface and the undersurface passes a current through the thermoelectric device assembly 1. The current flows from the high temperature side to the low temperature side in the P-type thermoelectric device 11 (from the top to the bottom in FIG. 4) while the current flows from the low temperature side to the high temperature side in the N-type thermoelectric device 12 (from the bottom to the top in FIG. 4). Thus, the thermoelectric devices connected in series form an electric circuit. The thermoelectric devices connected in series are joined on a flat surface or a line, constituting the thermoelectric device assembly 1.

In this configuration, the P-type thermoelectric device that is a silicon-magnesium device has a coefficient of thermal expansion of 4.5×10⁻⁶K⁻¹ while the N-type thermoelectric device 12 that is a silicon-magnesium device has a coefficient of thermal expansion of 15.5×10⁻⁶K⁻¹. It is found that an amount of expansion/contraction varies between the P-type thermoelectric device 11 and the N-type thermoelectric device 12 during heating in a joining process or a temperature change in an actual use environment. In the case where the thermoelectric device is joined to the electrode, a stress and distortion are generated near the joint by a difference in coefficient of thermal expansion between an electrode member and the thermoelectric device. Thus, the joint may be broken or peeled, or a crack may occur on the P-type thermoelectric device 11 or the N-type thermoelectric device 12.

In the structure of the present embodiment, however, a difference in coefficient of thermal expansion is 1.3×10⁻⁶K⁻¹ between the P-type thermoelectric device 11 composed of silicon-germanium (a coefficient of thermal expansion of 4.5×10⁻⁶K⁻¹) and the P-type electrode 211 composed of molybdenum (a coefficient of thermal expansion of 5.8×10⁻⁶K⁻¹). Such a small difference in coefficient of thermal expansion can reduce a stress or distortion near the joints of the P-type thermoelectric device 11.

Similarly, a difference in coefficient of thermal expansion is 0.3×10⁻⁶K⁻¹ between the N-type thermoelectric device 12 composed of silicon-magnesium (a coefficient of thermal expansion of 15.5×10⁻⁶K⁻¹) and the N-type electrode 221 composed of nickel (a coefficient of thermal expansion of 15.2×10⁻⁶K⁻¹). This can reduce a stress and distortion near the joints of the N-type thermoelectric device 12, forming the joints with high connection reliability.

Furthermore, in the present embodiment, a stress buffer layer does not need to be formed beforehand on the thermoelectric device. This can simplify the manufacturing process of the thermoelectric devices while reducing the total number of configurations in the thickness direction, leading to smaller variations in height.

Moreover, the joining pattern of the present invention reduces the absolute values of a stress and distortion on the joint as compared with an electrode made of a single material in FIG. 6. Hence, even at a use environment temperature around 600° C., a considerable reduction in connection reliability can be suppressed.

In FIG. 4, the P-type electrode 211 is L-shaped. The N-type electrode 221 may be L-shaped instead. Preferably, the L-shaped electrode is made of a material having high thermal conductivity and high electric conductivity. According to the present embodiment, the ratio of the material having high thermal conductivity is increased relative to the volume of the electrode assembly 201, achieving higher conversion efficiency in addition to the effect of the first embodiment.

### Third Embodiment

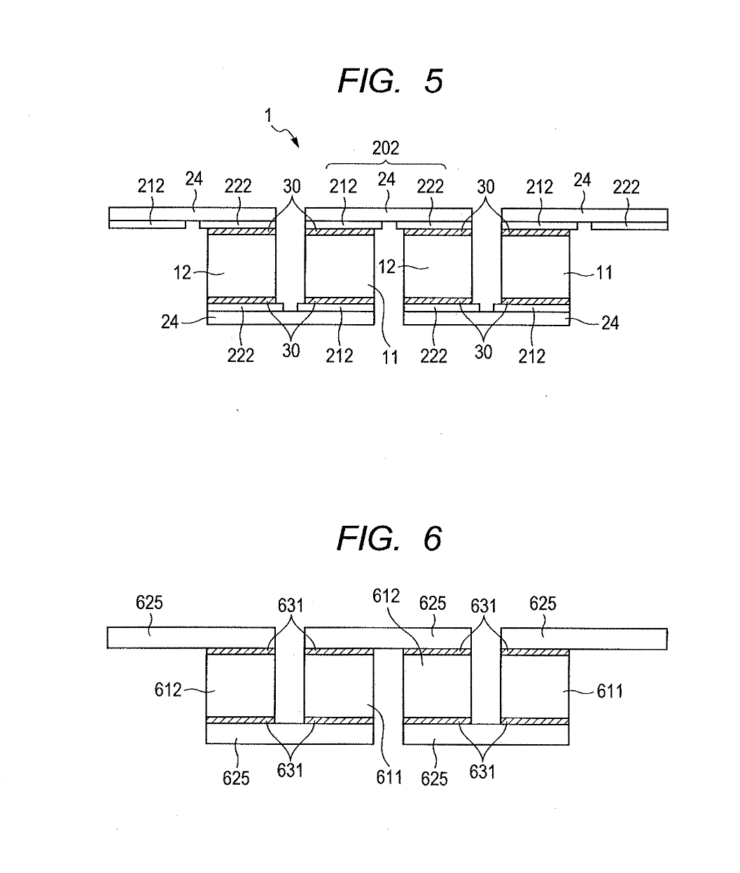

FIG. 5 is a side view of the vicinity of devices in a joint stress reducing thermoelectric module according to a third embodiment of the present invention. Reference numeral 1 denotes a thermoelectric device assembly, reference numeral 11 denotes a P-type thermoelectric device, reference numeral 12 denotes an N-type thermoelectric device, reference numeral 202 denotes an electrode assembly, reference numeral 212 denotes a P-type electrode, reference numeral 222 denotes an N-type electrode, reference numeral 24 denotes a support electrode, and reference numeral 30 denotes a bonding material. The present embodiment is different from the foregoing embodiments in that the electrode assembly 20 or 201 illustrated in the first and second embodiments includes the P-type electrode 212, the N-type electrode 222, and the support electrode 24.

The P-type thermoelectric device 11 and the N-type thermoelectric device 12 are made of materials having thermoelectric conversion characteristics, for example, silicon-germanium, iron-silicon, bismuth-tellurium, magnesium-silicon, lead-tellurium, cobalt-antimony, bismuth-antimony, a Heusler alloy, and a half Heusler alloy. The P-type electrode 212 and the N-type electrode 222 are desirably made of nickel, molybdenum, titanium, iron, copper, manganese, tungsten, or an alloy mainly composed of one of the metals. The support electrode 24 is preferably made of a material having a coefficient of thermal expansion between the coefficients of thermal expansion of the P-type electrode 212 and the N-type electrode 222. The bonding material 30 is desirably aluminum, nickel, tin, copper, zinc, germanium, magnesium, gold, silver, indium, lead, bismuth, tellurium, or an alloy mainly composed of one of the metals.

In the following embodiment, the P-type thermoelectric device 11 is made of silicon and germanium powder containing impurities of 1% or less with P-type semiconductor properties, for example, boron, aluminum, and gallium while the N-type thermoelectric device 12 is made of silicon and germanium powder containing impurities of 10% or less with N-type semiconductor properties, for example, aluminum. The thermoelectric devices are formed by sintering the powder by pulse discharge, hot pressing, and other methods. Specifically, in the present embodiment, the P-type thermoelectric device 11 is a silicon-germanium device while the N-type thermoelectric device 12 is a silicon-magnesium device. Furthermore, the P-type electrode 212 is made of molybdenum (a coefficient of thermal expansion of 5.8×10⁻⁶K⁻¹) while the N-type electrode 222 is made of nickel (a coefficient of thermal expansion of 15.2×10⁻⁶K⁻¹). The support electrode 24 is made of titanium (a coefficient of thermal expansion of 8.9×10⁻⁶K⁻¹).

The P-type electrode 212 may be joined to the support electrode 24 while the N-type electrode 222 may be joined to the support electrode 24 by any methods as long as remelting does not occur under a use environment. For example, the electrodes may be joined with a base material directly melted by electron beam welding, arc welding, spot welding, TIG welding, and other methods. Alternatively, the electrodes may be joined by solid-phase bonding such as a rolling process with a clad metal or may be joined with a bonding material such as a brazing filler metal.

As shown in FIG. 5, the upper end of the P-type thermoelectric device 11 and the lower end of the P-type electrode 212 are joined to each other with the bonding material 30 while the upper end of the N-type thermoelectric device 12 and the lower end of the N-type electrode 222 are joined to each other with the bonding material 30. In the thermoelectric module, an electromotive force is generated according to a temperature difference between both ends of the thermoelectric device. In FIG. 5, the top surface of the thermoelectric device has a high temperature while the undersurface of the thermoelectric device has a low temperature.

A temperature difference between the top surface and the undersurface passes a current through the thermoelectric device assembly 1. The current flows from the high temperature side to the low temperature side in the P-type thermoelectric device 11 (from the top to the bottom in FIG. 5) while the current flows from the low temperature side to the high temperature side in the N-type thermoelectric device 12 (from the bottom to the top in FIG. 5). Thus, the thermoelectric devices connected in series form an electric circuit. The thermoelectric devices connected in series, are joined on a flat surface or a line, constituting the thermoelectric device assembly 1.

In this configuration, the P-type thermoelectric device that is a silicon-magnesium device has a coefficient of thermal expansion of 4.5×10⁻⁶K⁻¹ while the N-type thermoelectric device 12 that is a silicon-magnesium device has a coefficient of thermal expansion of 15.5×10⁻⁶K⁻¹. It is found that an amount of expansion/contraction varies between the P-type thermoelectric device 11 and the N-type thermoelectric device 12 during heating in a joining process or a temperature change in an actual use environment. In the case where the thermoelectric device is joined to the electrode, a stress and distortion are generated near the joint by a difference in coefficient of thermal expansion between an electrode member and the thermoelectric device. Thus, the joint may be broken or peeled, or a crack may occur on the P-type thermoelectric device 11 or the N-type thermoelectric device 12.

In the structure of the present embodiment, however, a difference in coefficient of thermal expansion is 1.3×10⁻⁶K⁻¹ between the P-type thermoelectric device 11 composed of silicon-germanium (a coefficient of thermal expansion of 4.5×10⁻⁶K⁻¹) and the P-type electrode 211 composed of molybdenum (a coefficient of thermal expansion of 5.8×10⁻⁶K⁻¹). Such a small difference in coefficient of thermal expansion can reduce a stress or distortion near the joints of the P-type thermoelectric device 11. Similarly, a difference in coefficient of thermal expansion is 0.3×10⁻⁶K⁻¹ between the N-type thermoelectric device 12 composed of silicon-magnesium (a coefficient of thermal expansion of 15.5×10⁻⁶K⁻¹) and the N-type electrode 222 composed of nickel (a coefficient of thermal expansion of 15.2×10⁻⁶K⁻¹). This can reduce a stress and distortion near the joints of the N-type thermoelectric device 12, forming the joints with high connection reliability.

The support electrode 24 is made of titanium having a coefficient of thermal expansion (coefficient of thermal expansion of 8.9×10⁻⁶K⁻¹) between those of molybdenum and nickel, thereby reducing a difference in expansion/contraction in the electrode assembly 20. Since the P-type electrode 212 and the N-type electrode 222 are independent from each other, the shape and size can be changed according to a device size.

Moreover, the joining pattern of the present invention reduces the absolute values of a stress and distortion on the joint as compared with an electrode made of a single material in FIG. 6. Hence, even at a use environment temperature around 600°, a considerable reduction in connection reliability can be suppressed.

In the present embodiment, two layers are stacked in the electrode assembly 202. The electrode assembly 202 may have a laminated structure of at least two layers.

The invention may be embodied in other specific forms without departing from the spirit or essential characteristics thereof. The present embodiment is therefore to be considered in all respects as illustrative and not restrictive, the scope of the invention being indicated by the appended claims, rather than by the foregoing description, and all changes which come within the meaning and range of equivalency of the claims are therefore intended to be embraced therein.

What is claimed is:

1. A thermoelectric device assembly comprising a P-type thermoelectric device and an N-type thermoelectric device that are electrically connected in series via an electrode member,
wherein the electrode member has a portion connected to the P-type thermoelectric device according to a coefficient of thermal expansion of the P-type thermoelectric device and a portion connected to the N-type thermoelectric device according to a coefficient of thermal expansion of the N-type thermoelectric device, and the connected portion of the electrode to the P-type thermoelectric device and the connected portion of the electrode to the N-type thermoelectric device are made of different materials.

2. The thermoelectric device assembly according to claim 1, wherein a difference in coefficient of thermal expansion between the connected portion of the electrode member to the P-type thermoelectric device and P-type thermoelectric device and a difference in coefficient of thermal expansion between the connected portion of the electrode member to the N-type thermoelectric device and the N-type thermoelectric device are absolute values not larger than 6×10⁻⁶K⁻¹.

3. The thermoelectric device assembly according to claim 1, wherein the P-type thermoelectric device and the N-type thermoelectric device each contain one of silicon-germanium, iron-silicon, bismuth-tellurium, magnesium-silicon, lead-tellurium, cobalt-antimony, bismuth-antimony, a Heusler alloy, and a half Heusler alloy.

4. The thermoelectric device assembly according to claim 1, wherein the connected portion of the electrode member to the P-type thermoelectric device and the connected portion of the electrode member to the N-type thermoelectric device are made of materials having different coefficients of thermal expansion.

5. The thermoelectric device assembly according to claim 1, wherein the connected portion of the electrode member to the P-type thermoelectric device and the connected portion of the electrode member to the N-type thermoelectric device are made of different materials and are joined by one of welding, solid-phase bonding, metal joining, and joining with a brazing filler metal.

6. The thermoelectric device assembly according to claim 1, wherein the electrode member is made of nickel, molybdenum, titanium, iron, copper, manganese, tungsten, or an alloy mainly composed of one of the metals.

7. A thermoelectric module comprising a plurality of P-type thermoelectric devices and a plurality of N-type thermoelectric devices that are alternately disposed so as to be electrically connected in series via electrode members,
Wherein each of the electrode members has a portion connected to each of the P-type thermoelectric devices according to a coefficient of thermal expansion of the P-type thermoelectric devices and a portion connected to each of the N-type thermoelectric devices according to a coefficient of thermal expansion of the N-type thermoelectric devices, and
the connected portion of each of the electrode members to each of the P-type thermoelectric devices and the connected portion of each of the electrode members to each of the N-type thermoelectric devices are made of different materials.

8. The thermoelectric module according to claim 7, wherein a difference in coefficient of thermal expansion between the connected portions of the electrode
members to the P-type thermoelectric devices and P-type thermoelectric devices and a difference in coefficient of thermal expansion between the connected portions of the electrode members to the N-type thermoelectric devices and the N-type thermoelectric devices are absolute values not larger than 6×10⁻⁶K⁻¹.

9. The thermoelectric module according to claim 7, wherein the P-type thermoelectric devices and the N-type thermoelectric devices each contain one of silicon-germanium, iron-silicon, bismuth-tellurium, magnesium-silicon, lead-tellurium, cobalt-antimony, bismuth-antimony, a Heusler alloy, and a half Heusler alloy.

10. The thermoelectric module according to claim 7, wherein each of the connected portions of the electrode members to each of the P-type thermoelectric devices and each of the connected portions of the electrode members to each of the N-type thermoelectric devices are made of materials having different coefficients of thermal expansion.

11. The thermoelectric module according to claim 7, wherein each of the connected portions of the electrode members to each of the P-type thermoelectric devices and each of the connected portions of the electrode members to each of the N-type thermoelectric devices are made of different materials and are joined by one of welding, solid-phase bonding, metal joining, and joining with a brazing filler metal.

12. The thermoelectric module according to claim 7, wherein each of the electrode members is made of nickel, molybdenum, titanium, iron, copper, manganese, tungsten, or an alloy mainly composed of one of the metals.

13. A method of manufacturing a thermoelectric module, comprising the steps of:
disposing a plurality of electrode members, each being made of at least two materials with a first area composed of a first material joined to one of P-type thermoelectric devices according to a coefficient of thermal expansion of the P-type thermoelectric devices and a second material joined to one of N-type thermoelectric devices according to a coefficient of thermal expansion of the N-type thermoelectric devices;
alternately disposing the P-type thermoelectric devices and the N-type thermoelectric devices with high temperature surfaces flush with each other and low temperature surfaces flush with each other, and
electrically connecting each of the P-type thermoelectric devices and each of the N-type thermoelectric devices in series by joining each of the alternately disposed P-type thermoelectric devices to each of the electrode members in the first area of each of the electrode members and joining each of the N-type thermoelectric devices to each of the electrode members in the second area of each of the electrode members.

14. The method of manufacturing a thermoelectric module according to claim 13, wherein a difference in coefficient of thermal expansion between the connected portions of the electrode members to the P-type thermoelectric devices and P-type thermoelectric devices and a difference in coefficient of thermal expansion between the connected portions of the electrode members to the N-type thermoelectric devices and the N-type thermoelectric devices are absolute values not larger than 6×10⁻⁶K⁻¹.

15. The method of manufacturing a thermoelectric module according to claim 13, wherein each of the connected portions of the electrode members to the P-type thermoelectric devices and the connected portions of the electrode members to the N-type thermoelectric devices are made of different materials and are joined by one of welding, solid-phase bonding, metal joining, and joining with a brazing filler metal.
